(19) United States
(12) Patent Application Publication
(10) Pub. No.: US 2022/0013367 A1
(43) Pub. Date: Jan. 13, 2022

(54) PLASMA TREATMENT APPARATUS, SEMICONDUCTOR MANUFACTURING APPARATUS, AND MANUFACTURING METHOD OF SEMICONDUCTOR DEVICE

(71) Applicant: Toshiba Memory Corporation, Tokyo (JP)

(72) Inventors: Yasuhito YOSHIMIZU, Yokkaichi (JP); Hiroyuki YASUI, Yokohama (JP); Yuya AKEBOSHI, Yokkaichi (JP); Fuyuma ITO, Yokkaichi (JP)

(73) Assignee: Toshiba Memory Corporation, Tokyo (JP)

(21) Appl. No.: 17/483,052

(22) Filed: Sep. 23, 2021

Related U.S. Application Data
(62) Division of application No. 16/028,574, filed on Jul. 6, 2018.

(30) Foreign Application Priority Data
Jul. 26, 2017 (JP) 2017-144709
Jan. 10, 2018 (JP) 2018-001802

(51) Int. Cl. H01L 21/306; H01J 37/32; H01L 21/67; H01L 21/02; H01L 21/311

(52) U.S. Cl. CPC H01L 21/30604; H01J 2237/327; H01J 37/3244; H01J 37/32458; H01L 21/6708; H01L 21/02238; H01L 21/31111; H01J 37/32715; H01L 21/02252; H01L 21/02164; H01L 21/30608; H01J 37/32; H01L 21/02054; H01J 37/32082; H01L 21/31138; H01J 37/32091; H01J 2237/338; H01J 2237/20214; H01L 21/67051; H01J 37/32825

(57) ABSTRACT

A plasma treatment apparatus includes a discharge device generating plasma under atmospheric pressure, and a nonmetallic tube capable of advancing the plasma generated in the discharge device. The discharge device includes a discharge body with an internal space, and the plasma being generated in the internal space. The nonmetallic tube is connected to the discharge body, and includes a material different from a material of the discharge body. The plasma is released from the nonmetallic tube to an environment under atmospheric pressure.

### CROSS-REFERENCE TO RELATED APPLICATIONS

This application is based upon and claims the benefit of priority from Japanese Patent Applications, No. 2017-144709, filed on Jul. 26, 2017, and No. 2018-001802, filed on Jan. 10, 2018; the entire contents of which are incorporated herein by reference.

### FIELD

Embodiments relate to a plasma treatment apparatus, a manufacturing apparatus and a manufacturing method of a semiconductor device.

### BACKGROUND

A plasma treatment apparatus is known, which generates plasma in a reduced-pressure environment and treats an object to he treated.

### BRIEF DESCRIPTION OF THE DRAWINGS

FIG. 1 is a schematic view illustrating a plasma treatment apparatus according to an embodiment;

FIG. 2A and FIG. 2B are schematic diagrams illustrating characteristics of the plasma treatment apparatus according to the embodiment;

FIG. 3 is a schematic diagram illustrating another characteristic of the plasma treatment apparatus according to the embodiment;

FIG. 4 is a schematic view illustrating a plasma treatment apparatus according to a variation of the embodiment;

FIG. 5A and FIG. 5B are schematic views illustrating a manufacturing process of a semiconductor device according to an embodiment;

FIG. 6A and FIG. 6B are schematic views illustrating another manufacturing process of the semiconductor device according to the embodiment;

FIG. 7A and FIG. 7B are schematic views illustrating yet another manufacturing process of the semiconductor device according to the embodiment;

FIG. 8 is a schematic view illustrating other manufacturing process of the semiconductor device according to the embodiment;

FIG. 9A to FIG. 9C are schematic cross-sectional views illustrating a manufacturing method of a semiconductor device according to the embodiment;

FIG. 10A to FIG. 10B are schematic cross-sectional views illustrating the manufacturing method of the semiconductor device according to the embodiment;

FIG. 11A to FIG. 11C are schematic cross-sectional views illustrating another manufacturing method of a semiconductor device according to the embodiment;

FIG. 12A to FIG. 12C are schematic cross-sectional views illustrating yet another manufacturing method of a semiconductor device according to the embodiment;

FIG. 13A to FIG. 14B are schematic views illustrating other a plasma treatment apparatus according to other variation of the embodiment; and

FIG. 15 is a schematic view illustrating other manufacturing method of a semiconductor device according to the embodiment.

### DETAILED DESCRIPTION

According to one embodiment, a plasma treatment apparatus includes a discharge device generating plasma under atmospheric pressure; and a nonmetallic tube capable of advancing the plasma generated in the discharge device. The discharge device includes a discharge body with an internal space, and the plasma being generated in the internal space. The nonmetallic tube is connected to the discharge body, and includes a material different from a material of the discharge body. The plasma is released from the nonmetallic tube to an environment under atmospheric pressure.

According to other embodiment, a manufacturing method of a semiconductor device is provided. The method includes providing a plasma treatment apparatus including a discharge device and a nonmetallic tube, the discharge device generating plasma under atmospheric pressure, and the plasma generated in the discharge device advancing through the nonmetallic tube; and treating a surface of a semiconductor wafer by irradiating the plasma released from the tube toward the semiconductor wafer in an environment under atmospheric pressure.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

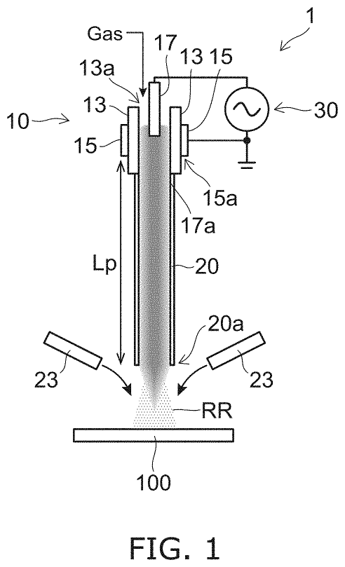

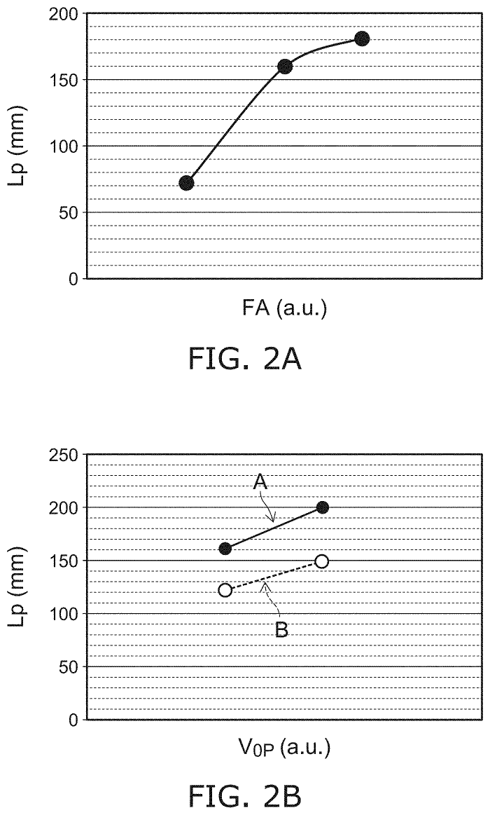

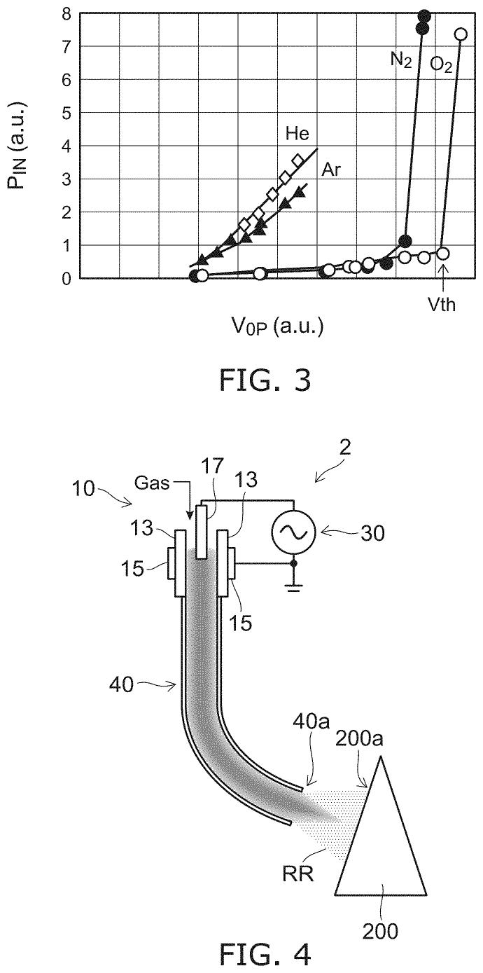

FIG. 1 is a schematic view illustrating a plasma treatment apparatus 1 according to an embodiment. FIG. 2A, FIG. 2B, and FIG. 3 are graphs illustrating characteristics of the plasma treatment apparatus 1.

The plasma treatment apparatus 1 includes a discharge device 10, a nonmetallic tube 20, and a high-frequency power source 30. The nonmetallic tube 20 is connected to the discharge device 10 that generates plasma, and serves as a channel wherethrough the plasma generated in the discharge device 10 advances. The plasma treatment apparatus 1 releases the plasma from an open end 20a of the tube 20 toward an object 100 to be treated,

As illustrated in FIG. 1, the discharge device 10 includes a tubular dielectric 13, an external electrode 15, and an internal electrode 17. The external electrode 15 is provided along an outer periphery of the tubular dielectric 13, and the internal electrode 17 is provided so that at least one end 17a thereof is positioned in an internal space of the tubular dielectric 13. The external electrode 15 and the internal electrode 17 are connected to the high-frequency power source 30. For example, the external electrode 15 is connected to a grounding side output of the high-frequency power source 30. The internal electrode 17 is connected to a high-voltage side output of the high-frequency power source 30.

The tube 20 is connected to one open end of the tubular dielectric 13 so that an internal space of the tube 20 is in communication with the internal space of the tubular dielectric 13. The tube 20 is preferably a nonmetallic insulated tube and is, for example, tubular glass or a tubular dielectric. The tube 20 is made of material, for example, different from the material of the tubular dielectric 13.

In the discharge device 10, plasma generation gas is introduced into the internal space of the tubular dielectric 13 via another open end 13a of the tubular dielectric 13. Then, plasma is generated in the internal space of the tubular dielectric 13 by a high voltage being supplied from the high-frequency power source 30 to the internal electrode 17. Moreover, the generated plasma advances along the internal space of the tube 20 due to the self-electric field thereof and is released to the outside from the open end 20a.

Here, “advancement” arises through the process where the gas inside the tube 20 is ionized and turned into plasma by the self electric field of the plasma generated in the discharge device 10, and further ionization of the gas inside the tube 20 takes place similarly by the self-electric field of the plasma generated inside the tube 20. Since the ionization process takes place repeatedly inside the tube 20 and progresses toward an open-end 20a from the discharge device 10, the plasma extends (or advances) toward the open-end 20a from the discharge device 10. Note that the “advancement” indicates a similar process in the following description,

For example, a high voltage of several kV at a high frequency of 15 kHz is applied between the external electrode 15 and the internal electrode 17 such that plasma is generated in the internal space of the tubular dielectric 13. This plasma advances toward the open end 20a while exciting the plasma generation gas inside the tube 20 by the self-electric field of this plasma. As a result, plasma is released to the outside from the open end 20a of the tube 20.

FIG. 2A is a graph illustrating a relationship between an advancement length Lₚ of the plasma and a flow rate FA of the plasma generation gas. The horizontal axis is the flow rate FA of the plasma generation gas supplied to the discharge device 10, and the vertical axis is the advancement length Lₚ. As illustrated in FIG. 2A, increasing the gas flow rate FA extends the advancement length Lₚ in the plasma treatment apparatus 1,

FIG. 2B is a graph illustrating a relationship between an amplitude V₀ₚ of a maximum voltage applied from the high-frequency power source 30 and the advancement length Lₚ. The horizontal axis is the amplitude V₀ₚ of the maximum voltage, and the vertical axis is the advancement length Lₚ. Moreover, FIG. 2B illustrates the characteristics A and B corresponding to different relative positions of the end 17a of the internal electrode 17 to the external electrode 15.

The characteristic A corresponds to a case where the end 17a of the internal electrode is shifted to a position on the open end 13a side in the tubular dielectric 13 with respect to the external electrode 15, and the characteristic B corresponds to a case where the end 17a of the internal electrode is shifted to a position on the tube 20 side with respect to the external electrode 15. Both characteristics A and B exhibit that increasing the amplitude V₀ₚ of the maximum voltage extends the advancement length L₀ₚ. Moreover, it is found that positioning the end 17a of the internal electrode on the tube 20 side extends the advancement length Lₚ farther.

In this manner, the advancement length Lₚ of the plasma can be lengthened by increasing the gas flow rate FA and increasing the amplitude V₀ₚ of the maximum voltage. According to FIG. 2A and FIG. 2B, the advancement length Lₚ can be extended to about 200 millimeters (mm) in the plasma treatment apparatus 1. Thereby, the object 100 can be separated in terms of distance from the discharge device 10, and it becomes possible to mitigate damage of the object 100 due to unintentional discharge, and to apply plasma treatment even on an object of a complex shape. Note that the longer the advancement length, the more favorable it is; for example, no less than 50 millimeters (mm) is preferable. That is, it is also preferable for a length of the tube 20 to be no less than 50 mm.

Furthermore, FIG. 3 is a graph illustrating a relationship between the amplitude V₀ₚ of the maximum voltage and a plasma power P_{IN} in terms of a type of the plasma generation gas supplied to the discharge device 10. The horizontal axis is the amplitude V₀ₚ of the maximum voltage, and the vertical axis is the plasma power P_{IN}.

As illustrated in FIG. 3, in a case where nitrogen N₂ or oxygen O₂ is used as the plasma generation gas, the plasma power P_{IN} rapidly increases when the amplitude V₀ₚ of the maximum voltage exceeds a threshold Vth. In contrast, with helium He and argon Ar, the plasma power P_{IN} increases starting from a voltage lower than the threshold Vth of nitrogen and oxygen, and shows a gradual increasing tendency. That is, when using a noble gas such as helium or argon, it is possible to improve an efficiency of plasma generation by high-frequency power.

As illustrated in FIG. 1, in the plasma treatment apparatus 1, a gas port 23 that supplies a reactive gas toward the plasma can be disposed near the open end 20a of the tube 20. The reactive gas supplied from the gas port 23 is excited in the plasma, and generates reactive radicals RR. In a case where, for example, oxygen is supplied from the gas port 23, oxygen radicals are excited, and oxidize a surface of the object 100. Moreover, by supplying, for example, nitrogen from the gas port 23, it is also possible to excite nitrogen radicals, and to nitride the surface of the treatment target 100.

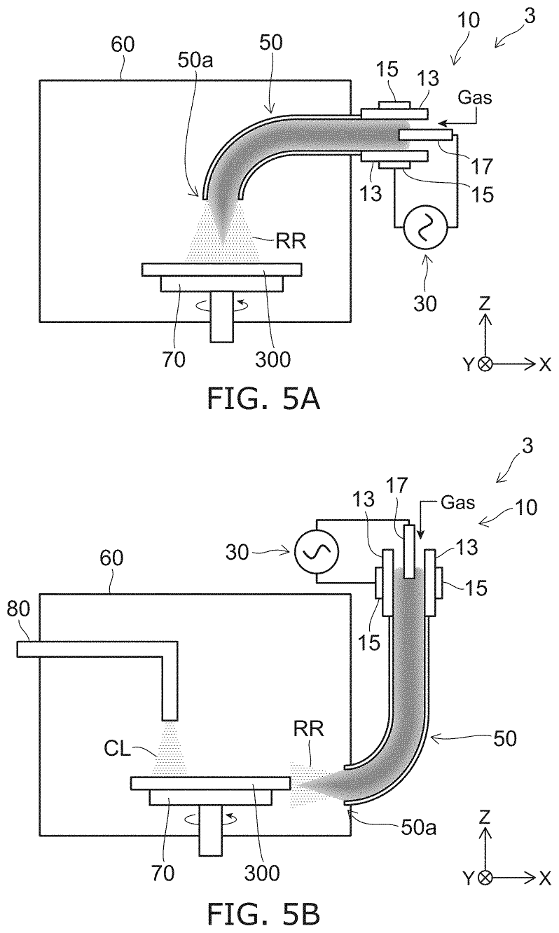

FIG. 4 is a schematic view illustrating a plasma treatment apparatus 2 according to a variation of the embodiment. The plasma treatment apparatus 2 includes the discharge device 10, the high-frequency power source 30, and a nonmetallic tube 40. The tube 40 is formed using, for example, silicone rubber or the like and is flexible, Thereby, an open end 40a can be made to face any direction in releasing the plasma.

As illustrated in FIG. 4, with the plasma treatment apparatus 2, it is possible to irradiate the plasma to, for example, a lateral face of an object 200 to be treated, which has a three-dimensional structure. Moreover, in the plasma treatment apparatus 2, the gas port 23 (see FIG. 1) can also be disposed near the open end 40a of the tube 40.

In this manner, according to the plasma treatment apparatus 1 and the plasma treatment apparatus 2 according to the embodiment, it is possible to lengthen an interval between the object and the discharge device 10, and to mitigate restrictions on a shape of the object, and the plasma treatment can be carried out without imparting damage to the treatment target due to unintentional discharge or the like.

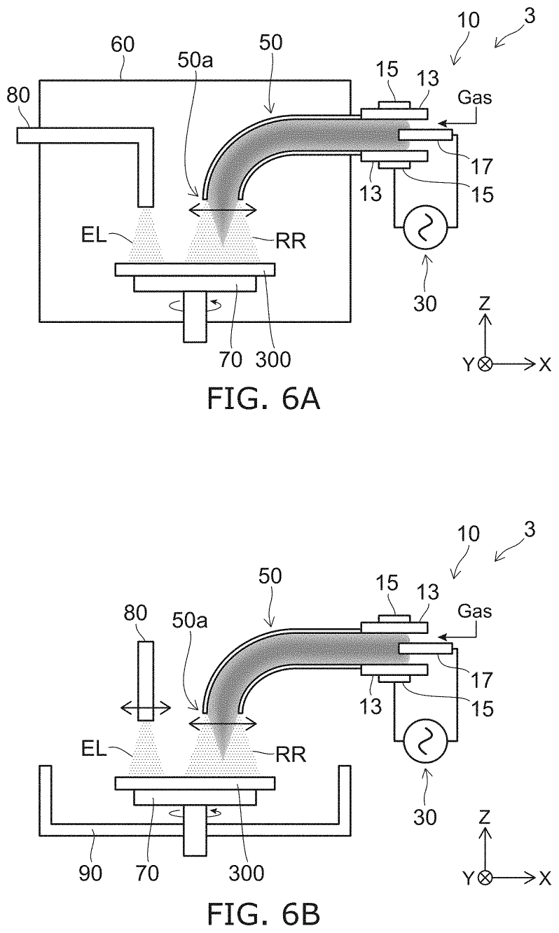

FIG. 5A and FIG. 5B are schematic views illustrating a manufacturing process of a semiconductor device according to the embodiment. FIG. 5A and FIG. 5B are schematic views illustrating processes of treating a semiconductor wafer 300 using a plasma treatment apparatus 3.

The plasma treatment apparatus 3 includes the discharge device 10, the high-frequency power source 30, and a nonmetallic tube 50. The tube 50 is connected to the discharge device 10 and serves as a channel through which the plasma generated in the discharge device 10 advances. That is, the plasma is released from an open end 50a of the tube 50 toward the semiconductor wafer 300.

As illustrated in FIG. 5A, the discharge device 10 is disposed outside a treatment chamber 60, and the tube 50 is inserted from the outside into the treatment chamber 60. Thereby, the plasma can be released from the open end 50a of the tube 50 toward a surface of the semiconductor wafer 300 that is placed on a stage 70 inside the treatment chamber 60. The stage 70 is, for example, provided so as to be capable of being rotated.

When the inside of the treatment chamber 60 is made to be an atmosphere including the reactive gas, it is possible to treat the surface of the semiconductor wafer 300 with the reactive radicals RR generated by the plasma released from the open end 50a. Alternatively, the gas port 23 (see FIG. 1) may be disposed near the open end 50a.

The surface of the semiconductor wafer 300 can be oxidized by using, for example, oxygen as the reactive gas. Moreover, an organic substance such as a resist formed on the semiconductor wafer 300 can also be removed by ashing, Normally, such oxidation or ashing is carried out in an environment under reduced pressure; however, treatment under atmospheric pressure becomes possible by using the plasma treatment apparatus 3. Thereby, no equipment is necessary to reduce pressure inside the treatment chamber 60. Moreover, a throughput of the manufacturing processes can be improved by eliminating the time required for pressure reduction. As a result, manufacturing costs may be reduced. Note that “under atmospheric pressure” here includes being under an environment near atmospheric pressure; such is also the case in the description below.

In the example illustrated in FIG. 5B, the plasma is released toward an edge of the semiconductor wafer 300. The semiconductor wafer 300 is placed, for example, on the rotatable stage 70. That is, by releasing the plasma toward the edge of the semiconductor wafer 30 while rotating the semiconductor wafer 300, the plasma can be irradiated to all edges of the semiconductor wafer 300.

For example, by making the inside of the treatment chamber 60 an atmosphere including the reactive gas, such as a fluorocarbon, the attached material deposited on the wafer edge can be removed by ashing. At this time, the plasma is not irradiated to a main face of the wafer, and thus, no damage of plasma arises. Moreover, the gas port 23 (see FIG. 1) may be disposed near the open end 50a of the tube 50 to supply the reactive gas.

Furthermore, since plasma treatment under atmospheric pressure becomes possible by using the plasma treatment apparatus 3, it is also possible to supply a cleaning liquid CL to the wafer surface together, for example. The cleaning liquid CL, which is supplied via a nozzle 80, removes particles, for example, which is difficult to remove treatment from the wafer surface with only the plasma. In this manner, treatment using the chemical and the plasma can be carried out at the same time by using the plasma treatment apparatus 3.

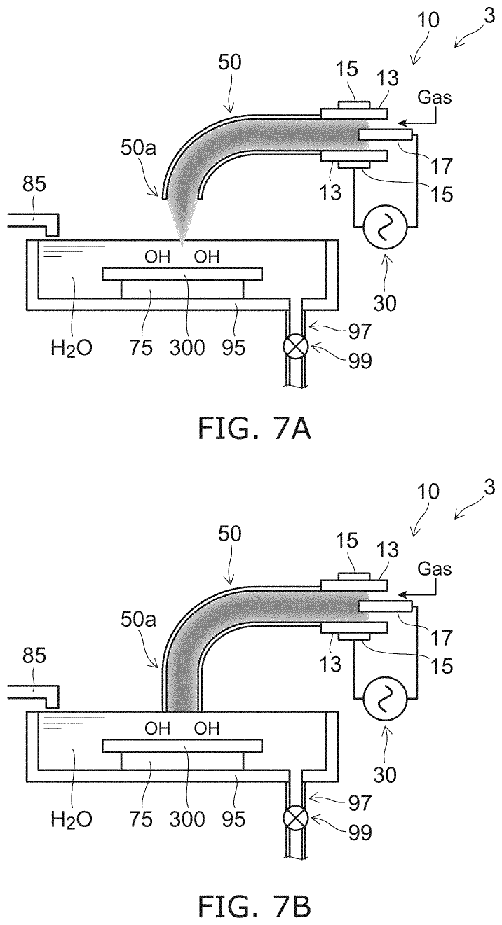

FIG. 6A and FIG. 6B are schematic views illustrating another manufacturing process using the plasma treatment apparatus 3. In the examples illustrated in FIG. 6A and FIG. 6B, the plasma is irradiated toward the surface of the semiconductor wafer 300 using the plasma treatment apparatus 3 and an etching liquid EL is supplied to the surface of the semiconductor wafer 300 from the nozzle 80.

In the example illustrated in FIG. 6A, the semiconductor wafer 300 is placed on the rotatable stage 70 inside the treatment chamber 60. The plasma generated in the discharge device 10 of the plasma treatment apparatus 3 is released toward a top face of the semiconductor wafer 300. At the same time, the etching liquid EL is supplied from the nozzle 80 to the top face of the semiconductor wafer 300.

By rotating the semiconductor wafer 300, the etching liquid EL can be supplied to the entire upper face. Moreover, by swinging the tube 50 of the plasma treatment apparatus 3 in an X direction parallel to the top face of the semiconductor wafer 300, the plasma can be irradiated to the entire surface of the semiconductor wafer 300.

For example, by making the inside of the treatment chamber 60 the atmosphere including the reactive gas, the reactive radicals RR can be generated to treat the surface of the semiconductor wafer 300, The gas port 23 (see FIG. 1) may be disposed near the open end 50a of the tube 50 to supply the reactive gas from the gas port 23 into the plasma. Thus, the composite effect of plasma treatment and wet etching can be obtained by supplying the etching liquid EL.

By using, for example, oxygen as the reactive gas, oxygen radicals are generated, and the surface of the semiconductor wafer 300 is oxidized. At the same time, the wafer surface can be etched by supplying the etching liquid EL that removes the oxide of the semiconductor wafer 300. Thus, the interior of the wafer can be selectively etched by plasma-oxidizing the surface of the semiconductor wafer 300 to improve an etching resistance thereof, and supplying the etching liquid of the semiconductor wafer 300 from the nozzle 80.

In the example illustrated in FIG. 6B, the semiconductor wafer 300 is placed on the stage 70 and disposed above a catch pan 90 of the etching liquid EL. By swinging the tube 50 of the plasma treatment apparatus 3 and the nozzle 80 in the X direction and a Y direction, plasma treatment and wet etching can be applied in a desired position on the wafer surface. The embodiment is not limited to this example; for example, the semiconductor wafer 300 and the catch pan 90 may be disposed inside the treatment chamber 60. Moreover, the gas port 23 (see FIG. 1) may be disposed near the open end 50a of the tube 50.

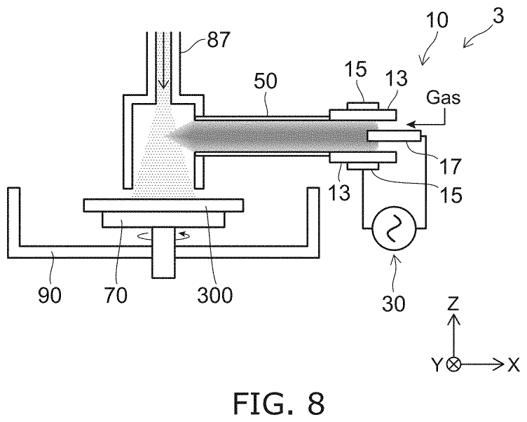

FIG. 7A and FIG. 7B are schematic views illustrating yet another manufacturing process using the plasma treatment apparatus 3. In the examples illustrated in FIG. 7A and FIG. 7B, the semiconductor wafer 300 is immersed in pure water inside a reservoir 95, and the plasma is released from the plasma treatment apparatus 3 toward the semiconductor wafer 300. The semiconductor wafer 300 is placed on a stage 75, and afterward immersed in the pure water. The pure water is supplied to the tank 95 from a nozzle 85, and the pure water after the treatment is discharged outside via a discharge port 97 and a valve 99.

As illustrated in FIG. 7A, hydroxyl radicals (OH), for example, are generated in the water covering the top face of the semiconductor wafer 300 by the plasma released from the tube 50 of the plasma treatment apparatus 3. Hydroxyl radicals are highly reactive and, for example, oxidize and remove the resist formed on the surface of the semiconductor wafer 300. Moreover, the resist formed on the surface of the semiconductor wafer 300 can be removed and particles adhered to the surface can also be removed by using a treatment liquid that can remove particles and the like on the wafer surface instead of the pure water.

As illustrated in FIG. 7B, the open end of the tube 50 may be positioned in the treatment liquid. Radical ions can be generated more efficiently by causing the plasma advanced via the tube 50 to contact the treatment liquid.

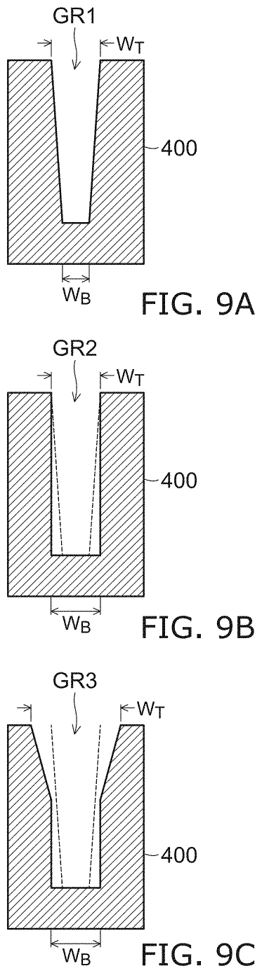

FIG. 8 is a schematic view illustrating other example of a manufacturing process using the plasma treatment apparatus 3. FIG. 8 illustrates an example where the plasma is released toward the treatment liquid, which is supplied from a nozzle 87 toward the semiconductor 300. In this example, the treatment liquid including the radicals generated by the plasma is supplied to the surface of the semiconductor wafer 300 disposed on the stage 70.

In this manner, by using the plasma treatment apparatus 3 that generates the plasma under atmospheric pressure, chemical treatment and plasma treatment can be carried out at the same time in the manufacturing process of the semiconductor device. Thereby, a manufacturing efficiency of the semiconductor device can be improved and the manufacturing costs can be reduced,

For example, in a manufacturing process of a nonvolatile semiconductor memory having a memory-cell array of a three-dimensional structure, as the stacking number of the memory cells increases, process steps and processing times required for deposition and etching increase significantly. Thus, increased manufacturing costs with three-dimensionalization for enlarging memory capacity may become a serious problem. In contrast, a throughput of the manufacturing process can be improved and the manufacturing costs can be reduced by using a plasma treatment apparatus that generates plasma under atmospheric pressure.

The plasma treatment apparatuses according to the embodiments can irradiate the plasma toward the object in a position away from the discharge device 10 by using the nonmetallic tube 20, the nonmetallic tube 40, or the nonmetallic tube 50 through which the plasma advances. Thereby, unintentional discharge between the electrode of the discharge device 10 and the object to be treated can be avoided, and plasma damage of the object can be prevented. Moreover, restrictions accompanying the shape of the treatment target can be mitigated, because the plasma advancing through the tube 20, the tube 40, or the tube 50 due to the self-electric field extends over a comparatively long distance.

In the manufacturing processes of the semiconductor device using the plasma treatment apparatus according to the embodiments, throughput can be improved and a new treatment due to the synergy effect between chemical treatment and plasma treatment can be achieved by carrying out the chemical treatment and plasma treatment at the same time.

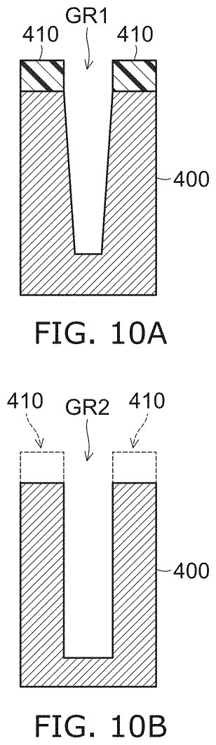

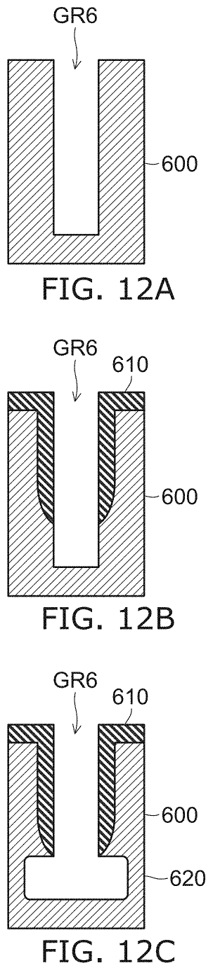

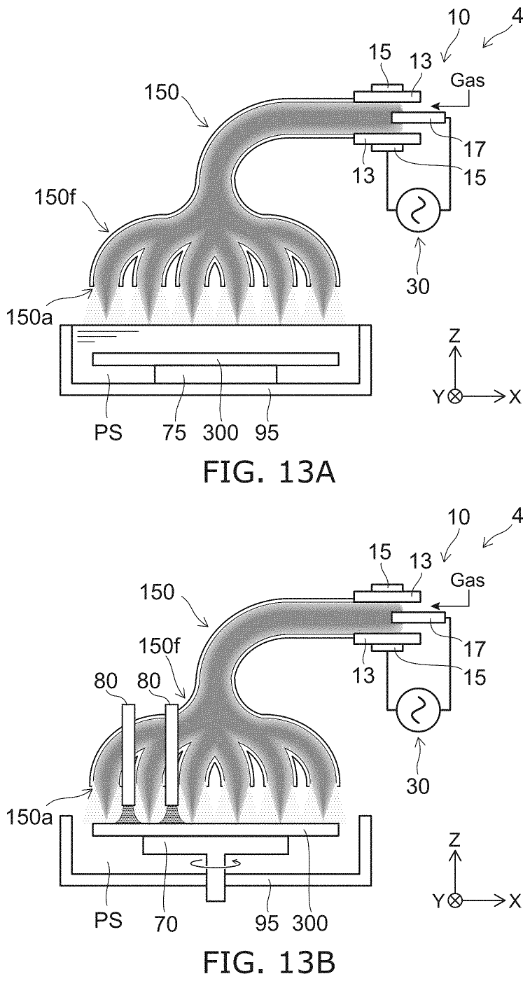

Next, a manufacturing method of a semiconductor device using an atmospheric-pressure plasma treatment apparatus is described with reference to FIG. 9A to FIG. 12C. FIG. 11A to FIG. 12C are schematic cross-sectional views illustrating the manufacturing method of a semiconductor device according to the embodiment.

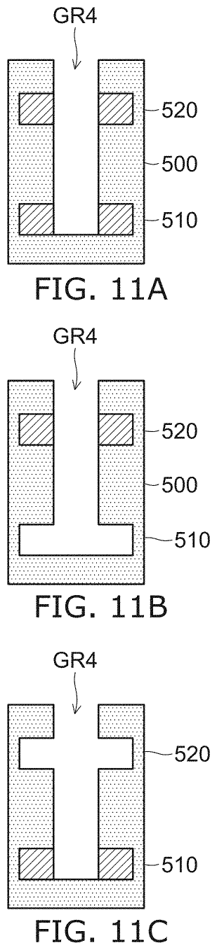

FIG. 9A to FIG. 10B are schematic views illustrating cross sections of a groove GR1 to a groove GR3 formed in a semiconductor wafer 400, respectively. FIG. 9A and FIG. 10A illustrate the groove GR1, which is formed using, for example, anisotropic RIE (reactive-ion etching), and FIG. 9B, FIG. 9C, and FIG. 10B illustrate the groove GR2 and the groove GR3, which are formed by a wet treatment with the atmospheric-pressure plasma.

Anisotropic RIE has etching characteristics depending on an incidence angle of the ions and adhesion of a sidewall polymer. In the groove GR1 formed by anisotropic RIE, a width W_{B} of a bottom face becomes narrower than an opening width W_{T} at the wafer surface. In contrast, the width W_{B} of the bottom face and the opening width W_{T} in the groove GR2 illustrated in FIG. 9B are formed so as to be substantially identical by wet etching with the atmospheric-pressure plasma.

For example, in a forming process of the groove GR2, radical ions that act to suppress etching of the semiconductor wafer 400 are generated using atmospheric-pressure plasma. For example, an alkali etching liquid is used for forming the groove GR2 in a silicon wafer. Then, OH radicals are formed in the liquid by the atmospheric-pressure plasma. The OH radicals oxidize the silicon and suppress dissolution of the silicon by the alkali etching liquid.

The radical ions in the treatment liquid lose activity, for example, by contacting a wall face of the groove GR2 through the process of moving in the groove GR2 toward the bottom face. That is, as the groove GR2 becomes deeper, more radicals are lost at a portion near the bottom face thereof such that an etching reaction of the semiconductor wafer 400 progresses. Thereby, the width W_{B} of the bottom face expands and can be formed to be substantially the same as the opening width W_{T}.

In the example illustrated in FIG. 9C, radical ions, for example, that act to promote the etching reaction of the semiconductor wafer 400 are generated by the atmospheric-pressure plasma. For example, an etching liquid including hydrofluoric acid is used for forming the groove GR3 in the silicon wafer. Then, OH radicals are formed in the liquid by the atmospheric-pressure plasma. The OH radicals form silicon oxide on a silicon surface, and the hydrofluoric acid dissolves the silicon oxide. Thereby, etching of the silicon wafer can be promoted more compared to a case where no OH radicals are generated.

Also in this case, the radical ions in the liquid contact a wall face of the groove GR3 and lose activity. Thus, a density of the radicals decreases in a depth direction of the groove CR3, and an effect of promoting etching also decreases in the depth direction. As a result, the groove CR3 has a tapered shape that opens upward at an upper portion thereof. Moreover, as the opening width W_{T} is expanded, compared to the example illustrated in FIG. 9A, etching at a bottom portion also progresses more and the width W_{B} of the bottom face becomes wider. Such a shape is advantageous in filling an inside of the groove GR3 with an insulating film or metal, preventing generation of voids.

As illustrated in FIG. 10A, the groove GR1 is formed by selectively etching the semiconductor wafer 400 using an etching mask 410. For example, resin resist can be used as the etching mask 410. The etching mask 41 is removed by, for example, asking or a chemical treatment after the groove GR1 is formed.

In the embodiment, as illustrated in FIG. 10B, the etching mask 410 is removed together with the etching of the semiconductor wafer 400. For example, the OH radicals generated by the atmospheric-pressure plasma ash and remove the resist when forming the groove GR2. Then, the etching conditions of the semiconductor wafer 400 can be set such that the etching mask 410 has been removed when forming groove GR2 is finished. In a case where wiring of silicon or device elements are provided under the etching mask 410, the etch mask 410 can be dissolved without imparting damage thereto.

FIG. 11A to FIG. 11C illustrate a method of selectively removing an embedded layer 510 and an embedded layer 520 provided in a structure 500 via a groove GR4.

As illustrated in FIG. 11A, the embedded layer 510 and the embedded layer 520 are exposed at an inner wall of the groove GR4. The embedded layer 510 is exposed at a bottom portion of the groove GR4, and the embedded layer 520 is exposed at an upper portion of the groove GR4. The embedded layer 510 includes, for example, the same material as a material of the embedded layer 520.

According to the etching method with atmospheric-pressure plasma of the embodiment, the embedded layer 510 can be selectively removed leaving the embedded layer 520 as illustrated in FIG. 11B.

For example, radicals that suppress etching of the material configuring the embedded layer 510 and the embedded layer 520 are generated by the atmospheric-pressure plasma and supplied inside the groove GR4. The radicals are generated in the atmosphere or in a treatment liquid. As described above, the radicals lose activity by contacting the inner wall of the groove GR4. Thus, the effect of suppressing etching by the radicals is lost at the bottom portion of the groove GR4, and the embedded layer 510 is selectively removed. Meanwhile, the embedded layer 520 is held at the upper portion of the groove GR4 by the effect of etching suppression effect of the radicals. Such etching is achieved by, for example, altering a surface of the embedded layer 520 exposed to the inner wall of the groove GR4 by the radicals and forming a coating thereon that is not dissolved by the treatment liquid.

For example, the embedded layer 510 and the embedded layer 520 are silicon layers and are embedded in a silicon-oxide film. Silicon, which is the material of the embedded layer 510 and the embedded layer 520, dissolves in alkali aqueous solutions such as ammonia water, a potassium hydroxide (KOH) solution, and tetramethylammonium hydroxide (TMAH).

For example, oxidizing radicals such as OH radicals generated by atmospheric-pressure plasma are supplied inside the groove GR4. The embedded layer 520 positioned at the upper portion of the groove GR4 is oxidized by the radicals, and has, for example, the silicon-oxide film formed on the surface thereof. Meanwhile, the radicals do not reach the embedded layer 510 positioned at the bottom portion of the groove GR4, and a surface thereof is not oxidized. Therefore, the embedded layer 510 dissolves in the alkali aqueous solution, and is selectively removed. Meanwhile, dissolution of the silicon is suppressed in the embedded layer 520 by the silicon-oxide film formed on the surface thereof. As a result, one of the embedded layer 510 and the embedded layer 520 exposed inside the groove GR4, which are of the same material, can be selectively removed by one etching process,

Furthermore, as illustrated in FIG. 11C, it is also possible to leave the embedded layer 510 and selectively remove the embedded layer 520. In this case, a treatment liquid that does not etch the embedded layer 510 and the embedded layer 520 is used, or an etching liquid that has slow etching speed of these embedded layers is used. Then, using atmospheric-pressure plasma, radicals that promote etching of the embedded layer 520 are generated in the treatment liquid. Thereby, the embedded layer 520 is etched at the upper portion of the groove GR4, where the radicals maintain activity. Meanwhile, the embedded layer 510 remains at the bottom portion of the groove GR4, where the radicals lose activity.

For example, in a case where the embedded layer 510 and the embedded layer 520 are metal layers that includes material such as tungsten or the like, it is possible to leave the embedded layer 510 and selectively remove the embedded layer 520 by using radicals that oxidize the metal layer and an etching solution that dissolves a metal oxide. That is, oxidizing radicals are supplied inside the groove GR4 and an oxidized coating is formed on the surface of the embedded layer 520. Then, etching of the embedded layer 520 is promoted by dissolving this oxidized coating. Meanwhile, the oxidizing radicals lose activity by contacting the inner wall of the groove GR4. Thus, no oxidized coating is formed on the surface of the embedded layer 510, and etching thereof is suppressed.

Alternatively, reducing radicals can be supplied by the atmospheric-pressure plasma. In this case, suppressing effect of etching the oxide can be obtained by reducing the oxide formed on the surface of the embedded layer 520. That is, to suppress etching of the embedded layer 520, reducing radicals are added to a chemical that etches the metal layer by an oxidation reaction. Meanwhile, the etching of the embedded layer 510 progresses at the bottom portion of the groove GR4 in which the reducing radicals lose activity. That is, it is possible to perform the process illustrated in FIG. 11B.

Furthermore, nitrogen radicals can also be generated by using nitrogen or ammonia gas as a reactive gas in the atmospheric-pressure plasma treatment apparatus according to the embodiment. Moreover, carbon radicals can also be generated by using methane, fluorocarbon, or the like as the reactive gas. That is, it is also possible to carry out etching rate control using nitrogen radicals or carbon radicals on the material exposed inside the groove GR4. Moreover, selective wet etching of a desired region can be performed by utilizing activity loss of the radicals.

To selectively remove one of the embedded layer 510 and the embedded layer 520 using a normal etching method, for example, the embedded layer 510 and the embedded layer 520 are formed of different materials or a protective film is formed on the surface of another one of the embedded layer 510 and the embedded layer 520. In contrast, according to the embodiment, such selective etching can be easily performed.

FIG. 12A to FIG. 12C illustrate a method of forming an expanded cavity in a bottom portion of a groove GR6. As illustrated in FIG. 12A, the groove GR6 is formed in a semiconductor wafer 600. The groove GR6 is formed using, for example, the method illustrated in FIG. 9B. The semiconductor wafer 600 is, for example, a silicon wafer.

As illustrated in FIG. 12B, an insulating film 610 is formed on a top surface of the semiconductor wafer 600 and an upper portion of the groove GR6. The insulating film 610 is formed using, for example, radicals generated in a treatment liquid by atmospheric-pressure plasma. The treatment liquid is, for example, pure water, and OH radicals are generated using the atmospheric-pressure plasma. As described above, the OH radicals lose activity by contacting an inner wall of the groove GR6. Thereby, the insulating film 610, which is, for example, a silicon-oxide film, can be formed on the upper face of the semiconductor wafer 600 and the upper portion of the groove GR6.

As illustrated in FIG. 12C, an etching liquid of the semiconductor wafer 600 is supplied via the groove GR6 to form a cavity 620. The cavity 620 is formed by etching the bottom portion, where the insulating film 610 is not formed, using, for example, an alkali etching liquid.

In this manner, wafer processing, which requires complex processes in the prior art, can be easily performed by using the atmospheric-pressure plasma. Note that in the manufacturing methods of a semiconductor device illustrated in FIG. 9A to FIG. 12C, ozone O₃ may be used instead of radicals generated by atmospheric-pressure plasma. For example, ozonated water or an etching liquid including ozone may be used as the treatment liquid.

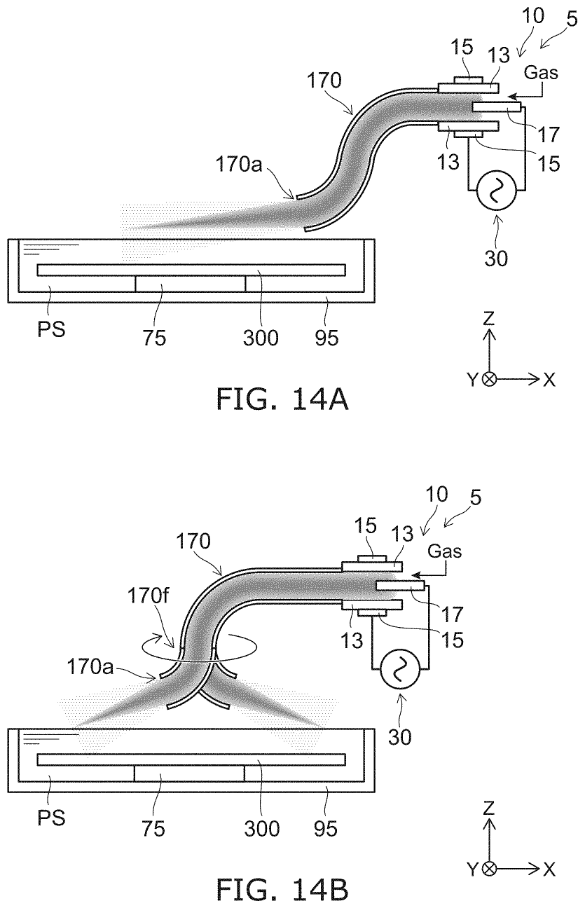

Herein below, plasma treatment apparatus 4 and 5 according to other variation of the embodiment are described with reference to FIGS. 13A to 14B. FIGS. 13A and 13B are schematic views illustrating the plasma treatment apparatus 4. FIGS. 14A and 14B are schematic views illustrating the plasma treatment apparatus 5.

The plasma treatment apparatus 4 includes a discharge device 10, a high-frequency power source 30, and a tube 150 of nonmetal. The tube 150 has a plurality of open ends 150a. That is, the tube 150 includes a plurality of sub-tubes 150f that are branched from a main portion linked to the discharge device 10, and releases plasma from each open end 150a of the sub-tubes 150f. Thereby, the plasma treatment apparatus 4 can irradiate over a wide area of an object to be treated with plasma.

As shown in FIG. 13A, the plasma-irradiation is performed toward a semiconductor wafer 300 placed in processing solution PS. It is possible in the plasma treatment apparatus 4 to simultaneously irradiate with plasma over an entire part of the processing solution PS that covers a front surface of the semiconductor wafer.

When the semiconductor wafer 300 is treated under the condition where the etching thereof is suppressed by plasma irradiation, for example, the etching proceeds at a portion not irradiated with the plasma. Thus, non-uniformity of etching may be generated when being locally irradiated with the plasma, In contrast, it is possible to uniformly treat the semiconductor wafer 300 by irradiating toward the whole front surface thereof with plasma, when the plasma treatment apparatus 4 is used.

As shown in FIG. 13B, the treatment solution PS is supplied from nozzles 80 to a frond surface of the semiconductor wafer 300, which is simultaneously irradiated with plasma using the plasma treatment apparatus 4. The semiconductor wafer 300 is preferably placed on a wafer holder 70 capable of turned around so as to be turned during the treatment. Also in this case, the semiconductor wafer 300 can be treated uniformly under the condition where the etching thereof is suppressed by plasma.

The plasma treatment apparatus 5 includes a discharge device 10, a high-frequency power source 30, and a tube 170 of nonmetal. The tube 170 has an open end 170a from which plasma is released in an oblique direction toward an object to be treated. For example, the tube 170 has the open end 170a from which the plasma is released toward a front surface of the object with an incident angle larger than 45 degree. Thereby, the plasma treatment apparatus 5 can irradiate over a wide area of an object to be treated with plasma. The irradiation area with plasma becomes larger as the incident angle of plasma is enlarged.

As shown in FIG. 14A, the plasma-irradiation is performed in a direction substantially in parallel to a front surface of a semiconductor wafer 300 placed in processing solution PS. Thereby, it is possible to irradiate with plasma over a wide area of the processing solution PS that covers a front surface of the semiconductor wafer.

As shown in FIG. 14B, the tube 70 may be configured to have an end portion 170f that is capable of turned around with respect to the main portion linked to the discharge device 10. That is, it is possible to irradiate with plasma over a wide area of the processing solution PS that covers the front surface of the semiconductor wafer 300 by making the end portion 170f of the tube 170 turn around.

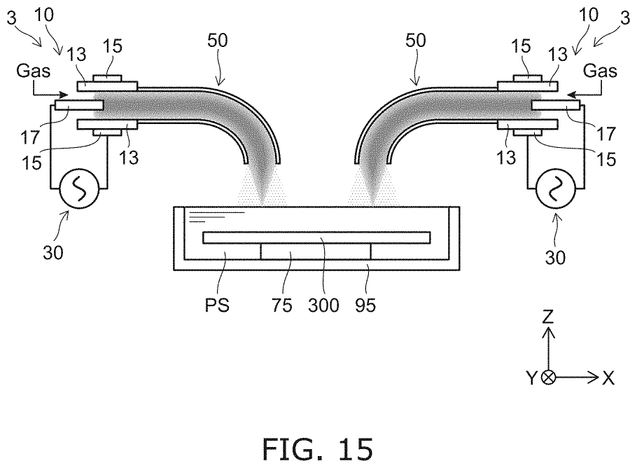

FIG. 15 is a schematic view illustrating other manufacturing method according to the embodiment. As shown in FIG. 15, a plurality of plasma treatment apparatus 3 are set so that plasma is released therefrom toward a semiconductor wafer 300 that is placed in the processing solution PS. Thereby, it is possible to uniformly treat the semiconductor wafer 300 by irradiating over a wide area of the processing solution PS that covers the front surface of the semiconductor wafer 300.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1-7. (canceled)

8. A manufacturing method of a semiconductor device comprising:
providing a plasma treatment apparatus including a discharge device and a nonmetallic tube, the discharge device generating plasma under atmospheric pressure, and the plasma generated in the discharge device advancing through the nonmetallic tube;
treating a surface of a semiconductor wafer by irradiating the plasma released from the nonmetallic tube toward the semiconductor wafer in an environment under atmospheric pressure.

9. The manufacturing method of a semiconductor device according to claim 8, wherein
the semiconductor wafer is placed in a liquid, and
the plasma is irradiated to the liquid between the nonmetallic tube and the semiconductor wafer.

10. The manufacturing method of a semiconductor device according to claim 8, wherein
the semiconductor wafer is treated by supplying a liquid treating the surface thereof, and
the plasma is irradiated to the liquid before reaching the surface of the semiconductor wafer.

11. The manufacturing method of a semiconductor device according to claim 9, wherein
the liquid etches a member attached to the surface of the semiconductor wafer.

12. The manufacturing method of a semiconductor device according to claim 8, wherein
a gas treating a member attached to the surface of the semiconductor wafer is supplied to the environment under atmospheric pressure.

13. The manufacturing method of a semiconductor device according to claim 12, wherein
a liquid treating the semiconductor wafer is supplied together with the gas.

14. A manufacturing method of a semiconductor device, comprising:
generating radicals in liquid using atmospheric-pressure plasma; and
promoting or suppressing etching of an object to be treated.

15. The manufacturing method of a semiconductor device according to claim 14, wherein
an inside of a concave portion provided in the object is selectively etched.

16. The manufacturing method of a semiconductor device according to claim 15, wherein
radicals suppressing etching of the object are generated, and a bottom face of the concave portion is expanded.

17. The manufacturing method of a semiconductor device according to claim 15, wherein
radicals promoting etching of the object are generated, and an opening of the concave portion is expanded.

18. The manufacturing method of a semiconductor device according to claim 15, wherein
one of a first structure and a second structure provided inside the object and exposed to an inner wall of the concave portion is selectively removed.

19. The manufacturing method of a semiconductor device according to claim 14, wherein
a coating is selectively formed on an inner face of the concave portion using radicals, and
a portion of the concave portion without the coating is selectively etched.

20. The manufacturing method of a semiconductor device according to claim 15, wherein
the concave portion is formed by using an etching mask provided on a surface of the object to selectively etch the object, and
the etching mask is removed while etching the object.

21-24. (canceled)
